(19) United States
(12) Patent Application Publication
(10) Pub. No.: US 2004/0125563 A1
(43) Pub. Date: Jul. 1, 2004

(54) Coating for a heat dissipation device and a method of fabrication

(76) Inventor: Joan K. Vrtis, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/334,732

(22) Filed: Dec. 31, 2002

(51) Int. Cl. H05K 7/20

(52) U.S. Cl. 361/704; 361/705; 361/719

(57) ABSTRACT

Numerous embodiments of a coating for a heat dissipation device and a method of fabrication are disclosed.

### BACKGROUND

A microelectronic device, such as a die, may be mounted to a substrate, forming a microelectronic assembly. In operation, a microelectronic device will generate heat. A heat dissipation device, such as a heat spreader, may be coupled to the microelectronic device, and may comprise part of the microelectronic assembly. The heat spreader may serve multiple purposes, including structural rigidity and thermal dissipation. Typically, a thermally conductive material is disposed between the die and the heat spreader to improve the thermal contact therebetween. The thermal performance of a microelectronic assembly may be affected by properties associated with the thermal interface material and the heat dissipation device, including wettability and adhesion. A need exists for a microelectronic assembly exhibiting consistent bond line control through improved adhesion and wettability properties, which may additionally be lower cost and/or easier to fabricate than state of the art solutions.

### BRIEF DESCRIPTION OF THE DRAWINGS

The subject matter regarded as the claimed subject matter is particularly pointed out and distinctly claimed in the concluding portion of the specification. Embodiments of the claimed subject matter, however, both as to organization and method of operation, together with objects, features, and advantages thereof, may best be understood by reference to the following detailed description when read with the accompanying drawings in which:

FIG. 1 is a cross sectional diagram of one embodiment of the claimed subject matter;

FIG. 2a is an obtuse plan view of one embodiment of the claimed subject matter;

FIG. 2b is an obtuse plan view of one embodiment of the claimed subject matter; and

FIG. 3 illustrates two methods of forming one or more embodiments of the claimed subject matter.

### DETAILED DESCRIPTION

Embodiments of the claimed subject matter may comprise an enhancement layer for a heat dissipation device and a method of fabrication. As stated previously, a microelectronic assembly may be comprised of a microelectronic die in thermal contact with a heat dissipation device. A heat dissipation device, such as a heat spreader, is usually located above the die, and is thermally coupled to the die by means of a thermal interface material. In one embodiment of the claimed subject matter, a method of fabricating a heat dissipation device comprises forming the heat dissipation device out of metal such as copper, and coating a substantial portion of the top and bottom surface of the device with a material that has the capability to enhance one or more characteristics of the device, including wettability and adhesion. This material may include, for example, silver, tin, palladium or an organic material such as organic surface protectant.

It is worthy to note that any reference in the specification to “one embodiment” or “an embodiment” means that a particular feature, structure, or characteristic described in connection with the embodiment is included in at least one embodiment of the claimed subject matter. The appearances of the phrase “in one embodiment” in various places in the specification are not necessarily all referring to the same embodiment.

Numerous specific details may be set forth herein to provide a thorough understanding of the embodiments of the claimed subject matter. It will be understood by those skilled in the art, however, that the embodiments of the claimed subject matter may be practiced without these specific details. In other instances, well-known methods, procedures and components have not been described in detail so as not to obscure the embodiments of the claimed subject matter. It can be appreciated that the specific structural and functional details disclosed herein may be representative and do not necessarily limit the scope of the claimed subject matter.

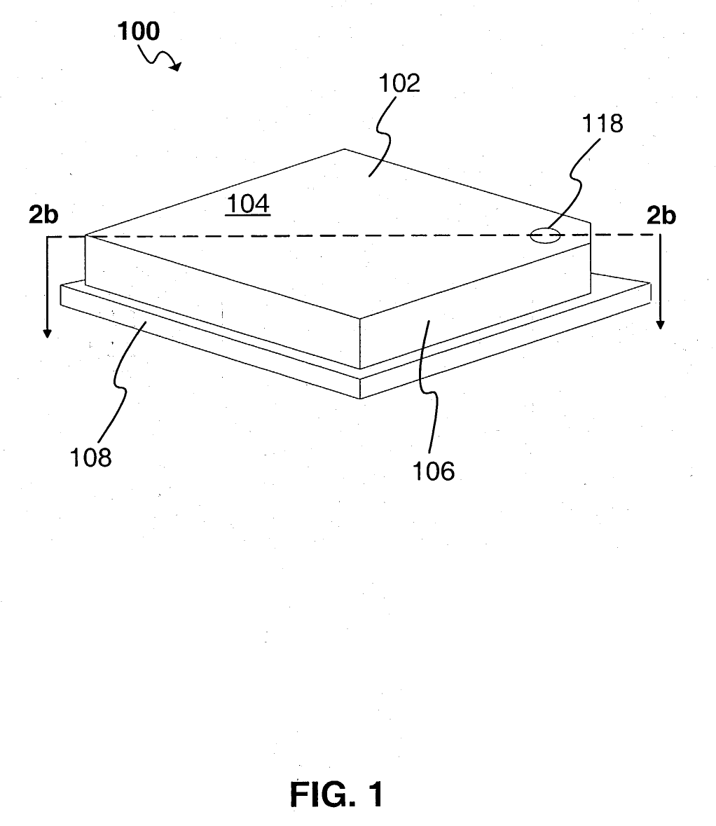

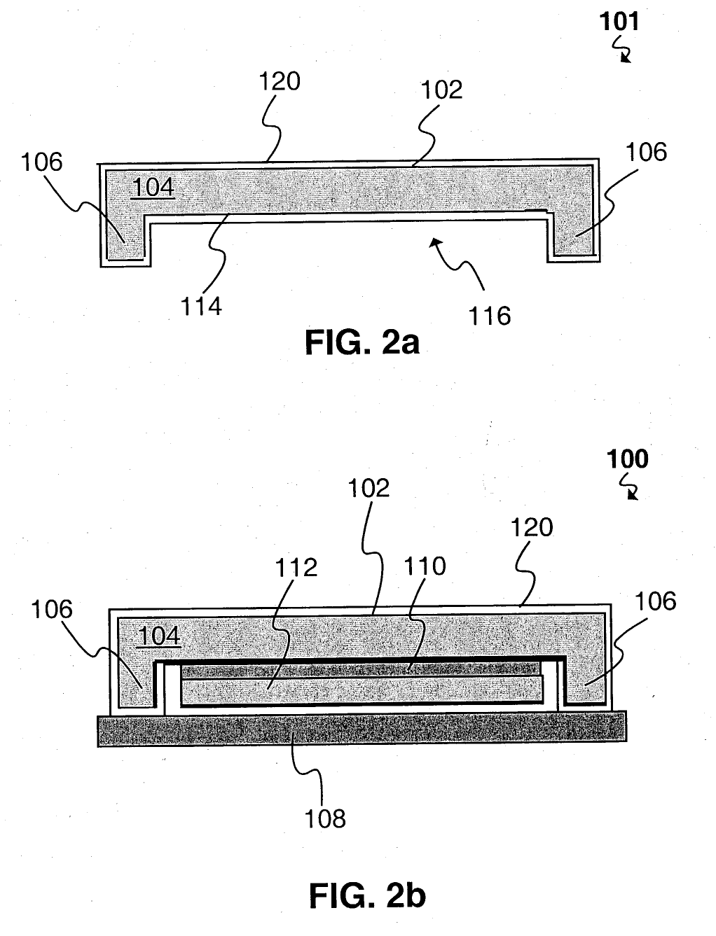

Referring now in detail to the drawings wherein like parts are designated by like reference numerals throughout, there is illustrated in FIGS. 1, 2a and 2b differing views of a microelectronic assembly 100, as well as subassemblies shown partially assembled as a microelectronic assembly. Microelectronic assembly 100 is comprised of a heat dissipation device 101 (see FIG. 2a), which may comprise, for example, a heat spreader or lid. Microelectronic assembly 100 may comprise at least one microelectronic die 112, illustrated here as a flip chip, however, the microelectronic die can be attached in any manner known in the art. Additionally, those skilled in the art will understand that the microelectronic die 112 can be any integrated circuit device including but not limited to any sort of microelectronic device such as a microprocessor, a chipset, an ASIC or the like. The microelectronic die 112 is coupled to substrate 108, which may comprise a printed circuit board (PCB), and may alternatively be referred to as a substrate carrier. Secondary electronic components, such as capacitors (not shown), may also be attached to the substrate 108. Typically, the microelectronic die 112 is attached to one side of the substrate 108, and attachment may be by means of a plurality of solder balls or solder bump connections (not shown), although those skilled in the art will recognize that alternative attachment methods exist. An underfill material (not shown) may be disposed between the microelectronic die and the substrate. In operation, electronic signals can be provided through the solder bump connections to and from the die 112. When fully assembled, die 112 is typically in thermal contact with the heat dissipation device 101 by means of a thermal interface material 110 applied to the back of the die, which may comprise, for example, thermal grease, phase change material, metal filled polymers or epoxies, or solder, for example. A vent hole 118 may be formed in the heat spreader, and may provide pressure relief inside the package.

Heat dissipation device 101 includes a body 104, and a top surface 102, which may be substantially planar, in one embodiment. Heat dissipation device 101 may comprise a bottom surface 114, which may be configured to receive one or more microelectronic dice such as die 112, and a substantially contiguous lip 106, which may, along with other recited components, form an inverted cap with an internal cavity 116. The substantially contiguous lip 106 may be configured to span around a substantial portion of the microelectronic die 112. This lip 106 may serve as an attachment point for the device subassembly 101 to attach to the substrate 108, for example. Device subassembly 101 may provide structural support for the entire package 200, and may, for example, reduce or prevent warpage of the substrate 108. Device subassembly 101 may be attached to substrate 108 by using solder, sealants, or other types of adhesive materials, although those skilled in the art will understand that numerous alternative attachment methods exist. Device 101 may be at least partially coated with an enhancement layer 120, which may provide enhanced properties for a device including wettability and adhesion, which will be explained in further detail hereinafter.

In operation, heat is typically conducted from the microelectronic die 112 through the thermal interface material 110 to the device subassembly 101 by heat conduction. A heat sink, such as a folded fin or an extruded pin heat sink, for example (not shown) may be attached to the top surface 102 of the device subassembly 101, and in operation, heat is transferred from the device 101 to the heat sink, and convective heat transfer primarily transfers heat from the heat sink to the surrounding air. A heat sink may be attached to a device 101 by use of an adhesive material, or a mechanical attachment mechanism, for example. It is important to note, however, that numerous configurations of heat sink as well as numerous methods of attachment exist, as is well known by those skilled in the art.

Heat dissipation device 101 may be comprised of a primary structure of copper, for example. The heat spreader device may optionally be substantially coated with a thin nickel layer (not shown). Additionally, a heat spreader, such as the heat dissipation device 101, may be selectively coated with a gold layer, wherein the selected portions may be the top layer 102 and the bottom layer 114, for example. Coating may be provided by masking off areas of the device that are not to be coated, and then providing one or more coating processes, such as electroplating or electroless plating, for example. As those skilled in the art are aware, the gold layer is formed in order to provide a wetting layer, and the nickel layer may be formed to at least partially provide a diffusion barrier between the gold and the copper, for example. However, forming a gold layer may be expensive and time consuming, and due at least to the cost of materials, additional masking process may be required, adding to the complexity of fabrication. Additionally, depending on the type of thermal interface material utilized in the assembly, properties including wettability and adhesion may be affected by the type of material used to coat the heat spreader. Gold may provide an adequate wetting layer as well as adequate adhesion for solder based thermal interface materials, which may include, for example, alloys of metals including zinc, copper, tin, lead, indium, or combinations thereof. However, gold plating may be expensive, time consuming, and result in low yield rates, and may not provide an adequate wettability layer for organic thermal interface materials, which may include, for example, polymer systems, grease based, or hybrid materials such as indium filled epoxy, for example.

In one embodiment of the claimed subject matter, a heat dissipation device, such as device 101, may be coated with an enhancement layer, which may comprise a material other than gold, in order to enhance wettability and/or adhesion in a relatively cost efficient or process efficient manner as compared to a gold layer. This enhancement layer may comprise a wettability and/or adhesion enhancement layer, and may be applied on selected portions of the heat dissipation device, for example, but may additionally be applied on the entire exposed surface of the device. The manner and amount of application may depend in part on the method or methods used to apply the enhancement layer, and the material or combination of materials used as the enhancement layer may determine the method of application. Numerous differing materials may be used as an enhancement layer, including, for example, silver, tin, palladium, or one or more organic materials such as organic surface protectant. Each material may incorporate one or more differing process steps in order to apply it to one or more areas of a device, and each differing type of material provides an enhancements to one or more properties of an assembled device, such as wettability and adhesion, as compared to a device with no wettability or adhesion enhancing layers, as will be explained in more detail later.

In one embodiment of the claimed subject matter, a heat dissipation device such as device 101 is formed from a primary structure of copper, and at least partially coated with an enhancement layer, such as layer 120. In this embodiment, enhancement layer may comprise a silver finish, which may further comprise an immersion silver finish, for example. The silver surface finish may provide protection of the underlying copper base structure from copper oxide formation. Additionally, a silver finish or coating may provide enhanced wettability and adhesion properties as compared to the copper material for different types of thermal interface materials, including organics and solder based materials, for example. The thickness of the enhancement layer may vary, and the claimed subject matter is not limited to any particular thickness, and thickness is typically dependent on the assembly application. It is envisioned that a silver enhancement layer may be as thin as approximately 0.2 microns, and provide desirable properties for the heat dissipation device, including enhanced wettability and adhesion, for example. However, as stated previously, thickness may depend on the particular application, and one particular application may utilize a heat dissipation device with an enhancement layer applied to a thickness of 0.8 microns, for example.

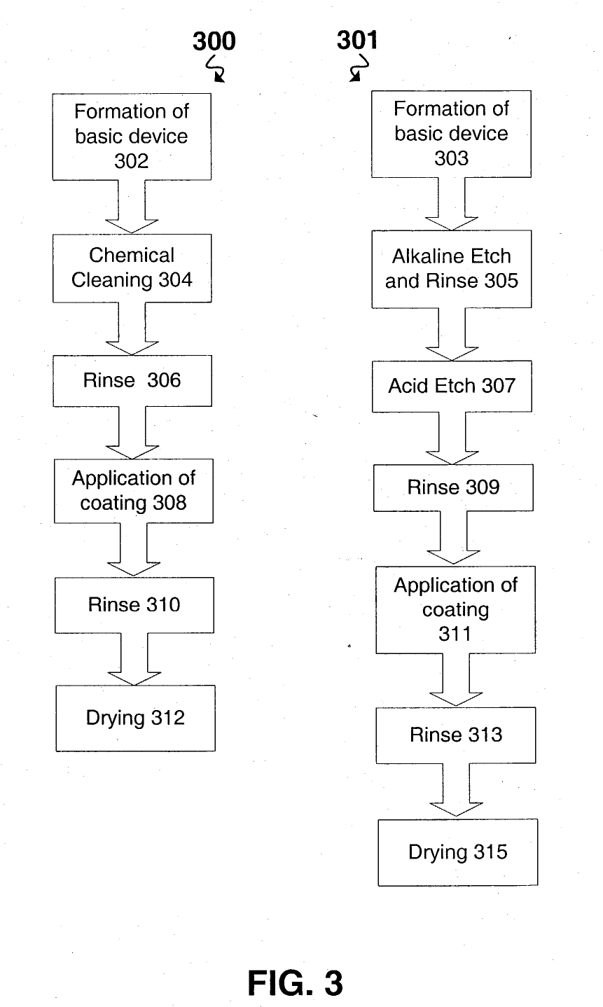

Although numerous methods of formation of a heat dissipation device with a silver enhancement layer may be used in accordance with the claimed subject matter, one particular method may be best illustrated by reference to FIG. 3, flowchart 300. It is important to note, however, that numerous steps herein may be modified or omitted, and still be in accordance with the claimed subject matter. A copper base material is formed into the basic device at functional block 302. The device may be subjected to chemical cleaning at block 304. One or more rinse steps may be performed on the device at functional block 306. An enhancement layer of silver may be provided on a substantial portion of the device at block 308. A rinse process may be incorporated at block 310, and subsequent to rinse 310, the coated device may be allowed to dry at block 314.

In one embodiment, a basic device, formed at functional block 302, may comprise a heat spreader, such as the heat spreader illustrated as item 101 of FIG. 2a. Formation may be by any number of methods, and the claimed subject matter is not limited in this respect. A chemical cleaning process 304 may comprise a dip of the device into one or more solutions, which may provide removal of impurities such as oil and oxidation from the surface of the device, and may provide a surface finish that is capable of receiving a coating such as an enhancement layer. One chemical cleaning agent may comprise an alkaline solution, for example. A rinse 306 subsequent to the chemical cleaning may be performed on the base material, and may comprise a water rinse in deionized water, for example.

In one embodiment, the device may be coated at functional block 308 with a silver enhancement layer by immersing the device in an immersion silver bath chemistry, although it is important to note that alternative methods for providing an enhancement layer exist, and any method of coating that provides a silver enhancement layer to at least a portion of a device such as device 101 may be used in accordance with at least one embodiment of the claimed subject matter. In this embodiment, the device is subjected to a dip plating process by immersing the device in a silver solution, such as the AlphaLEVEL™ solution available from Enthone®, Inc., or one or more solutions available from Uyemura, Inc. After undergoing a dip plating process, the base material may be subjected to another rinse process 310, which may again be a bath in deionized water, for example. After the rinse process, the coated device is typically allowed to dry at functional block 312, and then may be utilized in an assembly such as the assembly illustrated in FIG. 2b, for example.

In alternative embodiments, a silver surface finish may not be provided on a base material, but a different material such as palladium or tin may be provided on a substantial portion of the base material for use as an enhancement layer. The process used if these alternative embodiments are undertaken may be substantially similar to the process illustrated by flowchart 300, with the immersion process using, in the case of a tin enhancement layer, a solution of immersion tin available from Enthone, Inc., and in the case of palladium, a solution of palladium available from similar suppliers. In other alternative embodiments of the claimed subject matter, device 101 may be at least partially coated with a metal such as nickel, and then at least partially coated with an enhancement layer comprising silver, tin or palladium finish. As stated previously, one or more of these coatings may be less expensive, produce higher yield rates, and may provide comparable or enhanced wettability and/or adhesion properties when assembled in a microelectronic assembly as compared to a device coated with gold. The device provided with an enhancement layer may be assembled into a microelectronic assembly, such as assembly 100, for example. The thermal interface material 110 may be any type of thermal interface material, and depending on the type of thermal interface material used, the device may exhibit one or more improved characteristics as noted previously, For example, if the thermal interface material comprises a solder/polymer hybrid, the device coated with silver as an enhancement layer may exhibit improved wettability and adhesion properties.

In another embodiment of the claimed subject matter, an enhancement layer may be comprised of one or a combination of organic materials, which may enhance one or more properties of a device such as device 101, such as wettability and adhesion, for example. In this particular embodiment, a basic device such as device 101 may be formed from a primary structure of copper, and then selectively coated with an organic surface coating (OSP). The coating of OSP may enhance characteristics of the device, such as wettability and adhesion, for example. The thickness of the enhancement layer may vary, and the claimed subject matter is not limited to any particular thickness, but it is envisioned that an OSP based enhancement layer may be as low as approximately 50 Angstroms, and provide desirable properties for the heat dissipation device, although it is important to note that the thickness may vary based on the assembly application, the materials used, or on the method of application of the OSP, for example. Although numerous methods of formation of a heat dissipation device with an organic enhancement layer may be used in accordance with the claimed subject matter, one particular method may be best illustrated by reference to FIG. 3 flowchart 301. It is important to note, however, that numerous steps herein may be modified or omitted, and still be in accordance with the claimed subject matter. A basic device, which may comprise a copper base material, optionally coated with nickel, is formed at functional block 303. The device may be subjected to a chemical cleaning such as an alkaline etch, and a subsequent rinse at block 305. The device may undergo an acid etch at block 307, and may be rinsed after the acid etch, at functional block 309. A coating, such as an organic surface coating, may be provided on a substantial portion of the device at block 311 for use as an enhancement layer. The coated base material may be rinsed at functional block 313, and dried at functional block 315.

In one embodiment, the formation of a heat dissipation device with an organic enhancement layer may comprise formation of a copper base material at functional block 303, although the claimed subject matter is not limited to just a base material of copper, and any material or combination of materials providing desirable structural and/or heat dissipation properties may be used in accordance with one or more embodiments of the claimed subject matter. In this embodiment, a copper base material may comprise a heat spreader, such as the heat spreader illustrated as device 101 of FIG. 2a, and may optionally be coated with a nickel coating, for example. Formation may be by any number of methods, and the claimed subject matter is not limited in this respect. An alkaline etch and rinse 305 may comprise a dip of the device into one or more solutions, which may provide removal of impurities such as oil and oxidation from the surface of the device and etching of the surface, which may provide a surface finish that is capable of receiving a coating. One chemical cleaning agent may comprise an alkaline solution, for example. A rinse process follows the alkaline etch at functional block 305, and may comprise a water rinse such as a rinse in deionized water, for example.

In one embodiment, the base material may be microetched in an acid solution at functional block 307, in order to provide a surface suitable for coating, such as a matte surface. This etching process may be carried out in any suitable acid solution, such as a solution of nitric acid, for example. A water rinse 309, such as a rinse in deionized water, may be provided after the acid etch, and may provide a surface capable of receiving a coating such as an OSP enhancement layer.

In one embodiment, the device may be coated with an OSP at functional block 311 by dipping the device in a solution of OSP or spraying the device with a solution of OSP, although it is important to note that alternative methods for providing an enhancement layer exist, and any method of coating that provides an organic enhancement layer, such as layer 120, on at least a portion of a device such as device 101 may be used in accordance with at least one embodiment of the claimed subject matter. In this embodiment, the device is provided with an OSP by immersing the device in a OSP solution such as one or more solution available from Kester, Inc., such as the Protecto® product line, or from Enthone, Inc., such as Entek® products. It is important to note, however, that numerous solutions may be used to apply an OSP to the device, such as any organic solutions used to coat PCB lands, for example. After undergoing an immersion process, the device may be subjected to another rinse process 313, which may again be a bath in deionized water, for example. After the rinse process, the coated base material is typically allowed to dry at functional block 315, and then may be utilized in an assembly such as the assembly illustrated in FIG. 2b, for example. After coating with an OSP, the device may be assembled into a microelectronic assembly, such as assembly 100. The assembly may use any type of material as a thermal interface material, but utilization of solder as the thermal interface material may result in improved properties such as wettability and adhesion as compared to a device with a gold coating. In addition, the device with the OSP based enhancement layer may be less time consuming and more economical to fabricate.

It can be appreciated that the embodiments may be applied to the formation of any heat dissipation device wherein particular wettability and adhesion properties may be desirable. Certain features of the embodiments of the claimed subject matter have been illustrated as described herein, however, many modifications, substitutions, changes and equivalents will now occur to those skilled in the art. Additionally, while several functional blocks and relations between them have been described in detail, it is contemplated by those of skill in the art that several of the operations may be performed without the use of the others, or additional functions or relationships between functions may be established and still be in accordance with the claimed subject matter. It is, therefore, to be understood that the appended claims are intended to cover all such modifications and changes as fall within the true spirit of the embodiments of the claimed subject matter.

1. A microelectronic assembly, comprising:
a substrate having a microelectronic device attached thereto;
a thermal interface material applied to a substantial portion of the back surface of said microelectronic device; and
a heat dissipation device attached to the substrate, wherein the heat dissipation device has a top surface and a bottom surface, and is in physical contact with at least a portion of the thermal interface material, and wherein the heat dissipation device is at least partially comprised of copper, and is at least partially coated with an enhancement layer.

2. The assembly of claim 1, wherein the enhancement layer comprises one of the group consisting of silver, tin, palladium, and organic surface protectant.

3. The assembly of claim 1, wherein the substrate comprises a printed circuit board (PCB).

4. The assembly of claim 1, wherein the thermal interface material is a polymer based material.

5. The assembly of claim 1, wherein the thermal interface material is a solder based material.

6. The assembly of claim 1, wherein the thermal interface material is a polymer/solder hybrid based material.

7. The assembly of claim 1, wherein the heat dissipation device is coated with nickel, and is selectively coated with organic surface protectant, wherein the selected area coated comprises a substantial portion of the top surface and bottom surface of the heat dissipation device.

8. The assembly of claim 1, wherein the heat dissipation device is selectively coated with silver, wherein the selected area coated comprises a substantial portion of the top surface and bottom surface of the heat dissipation device.

9. The assembly of claim 1, wherein the heat dissipation device comprises a heat spreader.

10. A device, comprising:
a heat dissipation device, wherein the heat dissipation device has a top surface and a bottom surface, wherein the heat dissipation device is at least partially comprised of copper, and is selectively coated with silver, wherein the selected area coated comprises a substantial portion of the top surface and bottom surface of the heat dissipation device.

11. The assembly of claim 10, wherein the coating comprises an enhancement layer.

12. The assembly of claim 11, wherein the enhancement layer is further comprised of one of the group consisting of tin and palladium.

13. The assembly of claim 11, wherein the device comprises a nickel layer underlying the enhancement layer.

14. The method of claim 10, wherein the top surface and the bottom surface are substantially planar.

15. The method of claim 10, wherein the bottom surface is configured to receive a microelectronic device.

16. The method of claim 10, wherein the silver layer has a substantially uniform thickness of approximately 0.8 microns.

17. The assembly of claim 10, wherein the heat dissipation device comprises a heat spreader.

18. A device, comprising:
a heat dissipation device, wherein the heat dissipation device has a top surface and a bottom surface, wherein the heat dissipation device is at least partially comprised of copper, and is selectively coated with an organic surface protectant, wherein the selected area coated comprises a substantial portion of the top surface and bottom surface of the heat dissipation device.

19. The assembly of claim 18, wherein the coating comprises an enhancement layer.

20. The assembly of claim 19, wherein the device comprises a nickel layer underlying the enhancement layer.

21. The method of claim 18, wherein the top surface and the bottom surface are substantially planar.

22. The method of claim 18, wherein the bottom surface is configured to receive a microelectronic device.

23. The method of claim 18, wherein the silver layer has a substantially uniform thickness of approximately 0.2 microns.

24. The assembly of claim 18, wherein the heat dissipation device comprises a heat spreader.

25. A method for forming a heat dissipation device, comprising:
forming a heat dissipation device having a top surface and a bottom surface, wherein the device is substantially comprised of metal;
performing a chemical cleaning process on a substantial portion of the top and bottom surface of the device; and
coating at substantial portion of the top surface and the bottom surface with an enhancement layer, wherein the enhancement layer is comprised of one of the group consisting of silver, tin and palladium.

26. The method of claim 25, wherein forming further comprises forming the device out of copper.

27. The method of claim 25, wherein forming further comprises forming the top surface and the bottom surface to be substantially planar.

28. The method of claim 25, wherein the forming further comprises forming the bottom layer to a configuration capable of receiving a microelectronic device.

29. The method of claim 25, wherein coating comprises immersing the device in a silver solution for a particular period of time.

30. The method of claim 25, wherein coating comprises performing one or more spray processes on the device.

31. The method of claim 25, wherein coating comprises coating the device with the enhancement layer to an approximate thickness of 0.8 microns.

32. A method for forming a heat dissipation device, comprising:
forming a heat dissipation device having a top surface and a bottom surface, wherein the device is substantially comprised of metal;
performing a chemical cleaning process on a substantial portion of the top and bottom surface of the device;
performing an acid etch process on a substantial portion of the top and bottom surface of the device; and
coating at substantial portion of the top surface and the bottom surface with an enhancement layer, wherein the enhancement layer is comprised of an organic surface protectant.

33. The method of claim 32, wherein forming further comprises forming the device out of copper.

34. The method of claim 32, wherein forming further comprises forming the top surface and the bottom surface to be substantially planar.

35. The method of claim 32, wherein the forming further comprises forming the bottom layer to a configuration capable of receiving an microelectronic device.

36. The method of claim 32, wherein forming further comprises coating a substantial portion of the device with nickel.

37. The method of claim 32, wherein coating further comprises immersing the device in an organic surface protectant solution for a particular period of time.

38. The method of claim 32, wherein coating further comprises immersing the device in a solution substantially comprised of one of the group palladium and tin.

39. The method of claim 32, wherein coating further comprises performing one or more spray processes on the device, wherein the spray process uses one or more solutions of the selected material.

40. The method of claim 32, wherein coating further comprises performing one or more spray processes, wherein the one or more spray processes uses a solution of organic surface protectant.

41. The method of claim 32, wherein coating further comprises coating the device a material to an approximate thickness of 50 Angstroms.
